(19) United States
(12) Patent Application Publication
(10) Pub. No.: US 2010/0096253 A1
(43) Pub. Date: Apr. 22, 2010

(54) PVD CU SEED OVERHANG RE-SPUTTERING WITH ENHANCED CU IONIZATION

(75) Inventors: Yong Cao, San Jose, CA (US); Xianmin Tang, San Jose, CA (US); Tza-Jing Gung, San Jose, CA (US); Praburam Gopalraja, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC, Santa Clara, CA (US)

(21) Appl. No.: 12/256,428

(22) Filed: Oct. 22, 2008

(51) Int. Cl. C23C 14/34

(52) U.S. Cl. 204/192.1

(57) ABSTRACT

A method and apparatus for depositing metal on a patterned substrate are provided. A metal layer is formed in a physical vapor deposition process having a first energy. A second physical vapor deposition process is performed on the metal layer, using a second energy, wherein deposition interacts with brittle and plastic surface modification processes to form a substantially conformal metal layer on the substrate.

### BACKGROUND OF THE INVENTION

1. Field of the Invention

Embodiments of the invention relate to methods and apparatus for processing a substrate. More particularly, embodiments of the invention relate to methods and apparatus for depositing metal layers on a patterned substrate.

2. Description of the Related Art

Sputtering, also known as physical vapor deposition (PVD), is an important method of forming metallic features in integrated circuits. Sputtering deposits material in a layer on a substrate. A “target” is bombarded by ions strongly accelerated by an electric field. The bombardment ejects material from the target, and the material then deposits on the substrate.

Originally used to deposit material on a planar surface, sputtering has more recently been adapted to deposit material in trenches and vias formed on substrates. A dielectric layer is generally formed over a conductive layer or feature and patterned to expose the conductive feature at the bottom of a via or trench. A barrier layer is generally deposited to prevent interdiffusion between layers, and then metal is sputtered into the trench.

Sputtering is essentially ballistic in nature. Fast-moving ions barrel into the target, spraying particles from the target surface. The particles may be charged by the interaction with the incident ions through a charge transfer mechanism, they may be charged through interaction with any electric fields existing in the space, or they may remain uncharged. Deposition generally occurs faster on field regions and near the tops of trench sidewalls, as illustrated schematically in prior art FIG. 1. Substrate 10, with patterned dielectric 12, has been sputtered to deposit layer 14. Deposition has occurred faster near the top of side walls 16 and on field regions 18. This happens because ejected particles travel in all directions, rather than travelling in directions generally orthogonal to the substrate surface, and generally contact the substrate surface before penetrating deeply into the trench.

To encourage particles to travel into the trench before contacting the substrate surface, the particles may be ionized and accelerated under an electrical bias applied to the substrate. The accelerated ions travel more uniformly in a direction orthogonal to the surface of the substrate. As they approach the substrate surface, their momentum carries them into the trench, whereupon they deflect toward the trench sidewall under the influence of the electrical bias. Nonetheless, the deeper penetration into the trench reduces the effect of “overhang” near the top of the sidewall, but does not eliminate it entirely.

Overhang may result in metal plugs with holes or voids in them. If the deposition process is carried out too long, two overhang portions grow together over a trench, closing the trench to any future deposition, and forming a hole. Such holes are not conductive, and severely diminish the electrical conductivity of the formed feature. As devices formed on semiconductor substrates grow smaller and smaller, aspect ratio, the ratio of height to width, of trenches and vias formed in substrate layers grows larger. Higher aspect ratio geometries are more difficult to fill without voids. Sputtering processes are thus continually challenged to overcome the increasingly vexing problem of overhang management.

### SUMMARY OF THE INVENTION

Embodiments of the invention provide a method of processing a substrate having openings formed in a field region, comprising depositing a first metal layer on the substrate, depositing a second metal layer on the substrate, subjecting the first metal layer to a brittle surface modification process, and subjecting the first metal layer to a plastic surface modification process.

Other embodiments provide a method of depositing a conformal metal layer in openings formed in a field region of a substrate, comprising disposing the substrate on a substrate support in a processing chamber, depositing a first metal layer having thick regions and thin regions on the substrate in a physical vapor deposition process, depositing a second metal layer over the first metal layer in a physical vapor deposition process, and while depositing the second metal layer, simultaneously ejecting material from the first metal layer and redepositing the ejected material with the second metal layer, and pushing metal from the thick regions of the first metal layer to the thin regions of the first metal layer.

Other embodiments provide a method of depositing a conformal metal layer on a substrate having a field region and openings with sidewalls and bottom portions in the field region, comprising disposing the substrate on a substrate support in a process chamber, exposing the substrate to a first physical vapor deposition process comprising directing metal ions toward a surface of the substrate using a first electrical bias less than about 100V, depositing a first metal layer on the substrate, wherein the first metal layer has thick regions at the top of the sidewalls and bottom portions of the openings and thin regions on the sidewalls of the openings, exposing the substrate to a second physical vapor deposition process comprising directing metal ions toward a surface of the substrate using a second electrical bias of at least 250V, depositing a second metal layer on the substrate, dislodging material from the first metal layer at the bottom portions of the openings by bombarding the first metal layer with metal ions, and relocating the dislodged material, and moving material from the thick regions at the top of the sidewalls to the thin regions on the sidewalls.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a prior art substrate.

FIG. 2A is a flow diagram summarizing a method according to one embodiment of the invention.

FIGS. 2B-2E are schematic cross-sectional views of a substrate at various stages of the method of FIG. 2A.

FIG. 3A is a flow diagram summarizing a method according to another embodiment of the invention.

FIGS. 3B-3G are schematic cross-sectional views of a substrate at various stages of the method of FIG. 3A.

FIG. 4 is a cross-sectional view of an apparatus according to another embodiment of the invention.

FIG. 5 is a detail view of a portion of the apparatus of FIG. 4.

FIG. 6 is a plan view of one embodiment of a ring collimator.

FIG. 7 is a partial plan view of one embodiment of a honeycomb collimator.

FIG. 8A is a cross-sectional view of one embodiment of a substrate support.

FIG. 8B is a cross-sectional view of another embodiment of a substrate support.

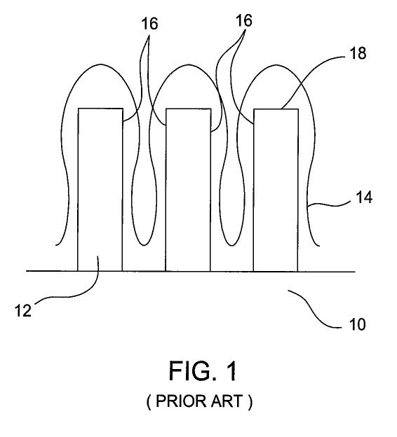

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally provide methods and apparatus for processing semiconductor substrates. The methods and apparatus described herein may be adapted to perform deposition processes, such as metal deposition processes or physical vapor deposition processes, on substrates. In general the term “substrates” as used herein can be formed from any material that has some natural electrical conducting ability or a material that can be modified to provide the ability to conduct electricity. Typical substrate materials include, but are not limited to, semiconductors, such as silicon (Si) and germanium (Ge), as well as other compounds that exhibit semiconducting properties. Such semiconductor compounds generally include group III-V and group II-VI compounds. Representative group III-V semiconductor compounds include, but are not limited to, gallium arsenide (GaAs), gallium phosphide (GaP), and gallium nitride (GaN). The term semiconductor substrates generally includes bulk semiconductor substrates as well as substrates having deposited layers disposed thereon. To this end, the deposited layers in some semiconductor substrates processed by the methods of the present invention are formed by either homoepitaxial (e.g., silicon on silicon) or heteroepitaxial (e.g., GaAs on silicon) growth. For example, the methods of the present invention may be used with gallium arsenide and gallium nitride substrates formed by heteroepitaxial methods. Similarly, the invented methods can also be applied to form integrated devices, such as thin-film transistors (TFTs), on relatively thin crystalline silicon layers formed on insulating substrates (e.g., silicon-on-insulator [SOI] substrates).

A variety of metals may be deposited using the methods and apparatus described herein. Although the methods described herein are particularly useful for depositing copper, other metals such as aluminum, cobalt, titanium, tantalum, tungsten, molybdenum, platinum, nickel, iron, niobium, palladium, and combinations or alloys thereof may also be deposited using these methods.

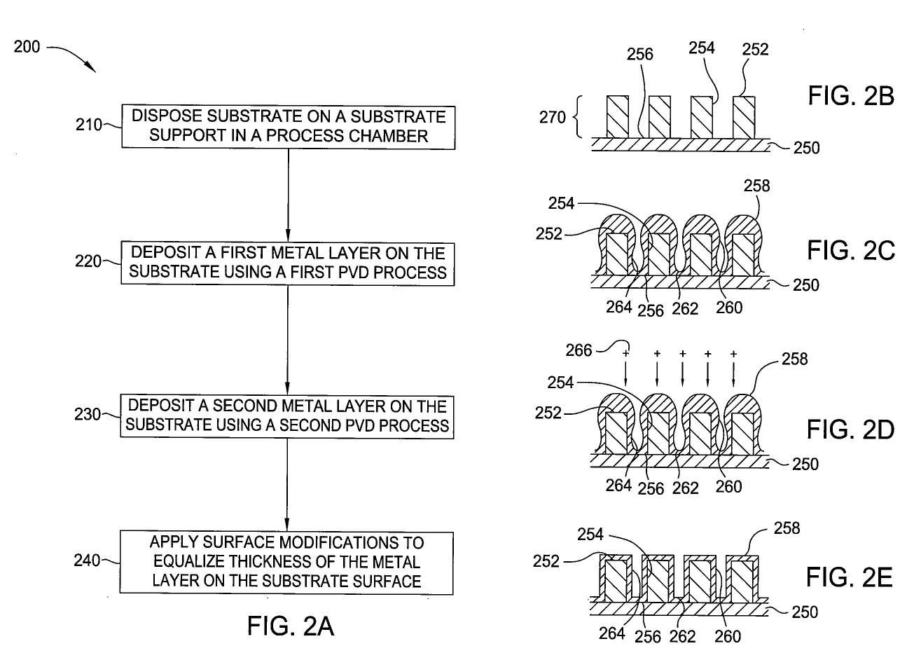

FIG. 2A is a flow diagram summarizing a method 200 according to one embodiment of the invention. A substrate is disposed in a process chamber at 210. FIG. 2B is a schematic cross-sectional diagram of a substrate that may be processed according to methods described herein. The substrate of FIG. 2B has an underlying layer 250, and a patterned layer 270 thereon. The underlying layer 250 may be conductive or semiconductive, and the patterned layer 270 will generally be a dielectric material. The patterned layer 270 generally has a field region 252, and trenches or vias having side walls 254 and bottom portions 256. The openings in the patterned layer will generally exhibit an aspect ratio greater than about 1:1, such as greater than about 4:1, for example greater than about 10:1.

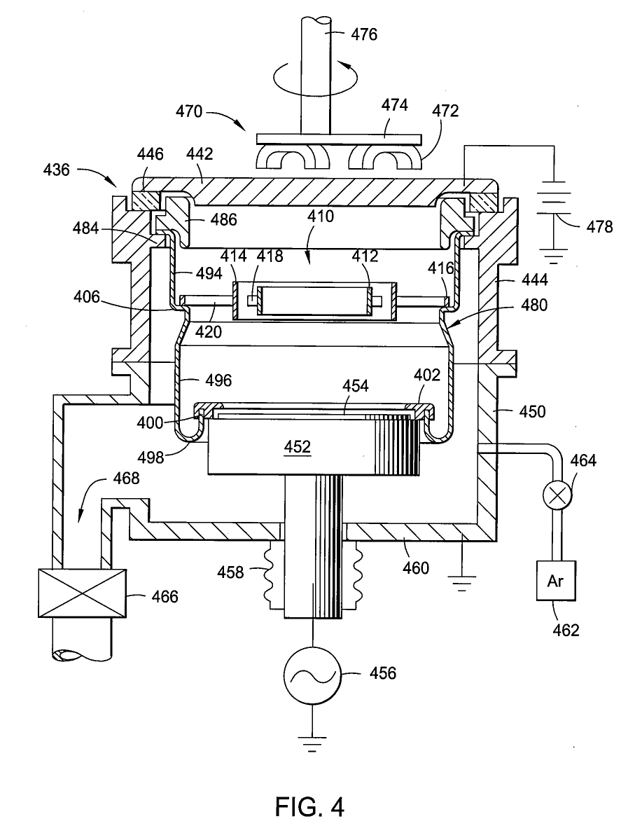

In general, the process chamber to be used for the method 200 will be configured to deposit a material on the substrate by bombarding the substrate with ions. Such an ion deposition chamber may be a physical vapor deposition (PVD) chamber in some embodiments. An exemplary chamber is described below in connection with FIG. 4.

At 220, a first metal layer is deposited over the substrate using a first PVD process. The first PVD process comprises providing a target having material to be deposited and generating an ion plasma proximate the target. The ions are propelled toward the target by an electromagnetic field established near the target, and upon impact eject material from the target. The ejected species may be neutral or electrically charged, and may change state thereafter by interaction with other particles in the plasma. The target may contain any material desirous of being deposited on the substrate. In one embodiment, the target is copper. In other embodiments, the target may be other metals, such as aluminum, cobalt, titanium, tantalum, tungsten, molybdenum, platinum, nickel, iron, niobium, palladium, and combinations thereof.

An electrical bias is applied to the target or the substrate to ionize the gases therebetween and to propel the ions toward the target. The bias may be DC or RF powered, and is generally between about 10V and about 2,400V, applied at a power level between about 50 Watts and about 1,000 Watts. In some embodiments, the bias voltage is between about 20V and about 100V, such as between about 30V and about 70V, for example about 50V, and the bias power is between about 100 Watts and about 200 Watts, such as about 120 Watts. In some embodiments, the bias is powered by RF power, which may be modified by a low or high-pass filter. The bias may be positive or negative and may be applied to the target or the substrate.

The substrate is generally held at a temperature selected to encourage accumulation of sputtered material on the substrate. In some embodiments, the substrate temperature is controlled between about 0° C. and about 600° C., for example about 75° C. In other embodiments, the substrate temperature may be higher than 5° C., such as between about 5° C. and about 600° C., or between about 20° C. and about 300° C., such as about 50° C. The chamber is typically maintained under vacuum. The chamber pressure may be less than about 10 Torr, such as less than about 1 Torr, or less than 100 mTorr, such as about 1 mTorr.

In some embodiments, it may be useful to increase alignment of particles depositing on the substrate. This may be done by interposing a physical alignment device, such as a collimator, through which the particles must travel to reach the substrate. Particles having trajectories that are too oblique strike and deposit on the collimator rather than the substrate. By use of an alignment device, the particles can be controlled to an angle of incidence with the substrate. For example, particle trajectories may be controlled such that no particle has an angle of incidence with the plane defined by the substrate surface that is less than about 60°. In some embodiments, the control angle may be even higher, such as about 70° or about 80°. As the control angle grows, however, particle flux and deposition rate decline because more particles are filtered out by the alignment device. Using a physical alignment device that controls angle of incidence above about 60°, for example, may result in a net reduction of mass flux between about 10% and about 50%, such as about 30%. Using such a device, a typical embodiment may achieve a mass flux of between about 5 μg/cm²·sec and about 100 μg/cm²·sec, such as between about 10 μg/cm²·sec and 50 μg/cm²·sec, for example about 30 μg/cm²·sec, depending also on the sputtering energy. In alternate embodiments, it may be advantageous to use electrostatic means to align the trajectories of ions being deposited by PVD. This avoids reducing mass flux and deposition rate.

A first metal layer is deposited on the substrate, as illustrated in FIG. 2C. A first metal layer 258 is deposited over the underlying layer 250 and the patterned layer 270, covering the field region 252, the side walls 254, and the bottom portions 256. As described above, the first metal layer has an overhang region 260, where the first metal layer is thicker than in a side wall region 264. Particles have increasing difficulty penetrating the restrictive opening formed by the encroaching overhang regions, and increasingly deposit on the field region 252. Consequently, formation of the bottom portion 262 of the first metal layer 258 covering the bottom portion 256 of the trench slows.

In most embodiments, the first metal layer will have a generally curved surface that follows the contours of the underlying substrate. The overhang regions and bottom portions usually have the most curvature, corresponding to the smallest radius of curvature. In some embodiments, the first metal layer has a radius of curvature less than the width of the openings formed in the underlying substrate. In some embodiments, the radius of curvature may be less than about half the width of the openings. In other embodiments, the curvature of the surface may be abrupt near the top of the openings, forming one or more substantially angular features near the top of the openings in the underlying substrate. In such embodiments, the portion of the first metal layer covering the field region comprises a capping portion. The one or more substantially angular features will be thinnest immediately above the top corner of the opening where the side wall region meets the field region.

A second metal layer is deposited on the substrate at 230. The second metal layer may have the same or different composition from the first metal layer. In some embodiments, the bias energy is increased to support a deposition process that includes modification of the surface of the first metal layer 258. The bias energy may be increased to between about 500 Watts and about 5,000 Watts, such as between about 800 Watts and about 3,000 Watts, for example about 1,000 Watts. The bias voltage may also be increased to between about 100V and about 2,500V, such as between about 200V and about 1,000V, for example about 350V. In some embodiments, the second deposition process comprises applying an RF bias and a DC bias to the target or the substrate. The RF and DC bias may each be applied at any of the power levels described above for the second deposition process.

The higher bias energy of the second deposition process imparts more energy to the substrate and the deposited metal layer disposed thereon. This energy results in surface modification of the deposited metal layer through brittle and plastic processes. Metal deposited in the first metal layer may be subjected to a surface modification process until the second metal layer develops, at which point the second metal layer may be subjected to the surface modification process. In a brittle surface modification process, ions accelerated by the increased bias impact the surface of the deposited metal layer and eject material therefrom. The ejected material re-deposits elsewhere on the surface of the deposited metal layer. In a plastic surface modification process, atoms from the deposited metal layer are pushed along the surface of the deposited metal layer from one location to another without leaving the surface.

FIG. 2D schematically illustrates the substrate undergoing the second deposition process described above. Ions 266 bombard the surface of the deposited metal layer 258. The ions 266 have directional trajectories oriented toward the substrate surface due to use of a physical alignment device, such as a collimator, or electrostatic alignment means, and therefore travel into the openings formed in patterned layer 270. Some of the ions impact the bottom portion 262 of the deposited metal layer, some impact the side wall portion 264, and some impact the overhang portion 260. Due to the energy of the impacts, some material is ejected from the deposited metal layer 258, for example from the bottom portion 262 of the deposited metal layer, and re-deposits on the deposited metal layer, for example on the side wall portion 264. Some impacts also push material along the surface of the deposited metal layer, for example from the overhang portion 260 to the side wall portion 264.

These surface modification processes are applied at 240 to equalize the thickness of the metal layer on the surface. In embodiments featuring the substantially angular feature or profile described above, deposition of metal ions during the second deposition process increases the thickness of the deposited metal layer near the top corner of the opening. The surface modification process moves deposited metal from thicker portions of the layer to thinner portions. FIG. 2E illustrates the substrate having undergone the surface modification processes 240. The deposited metal layer 258 has a substantially conformal profile resulting from the interacting deposition and surface modification processes 230 and 240.

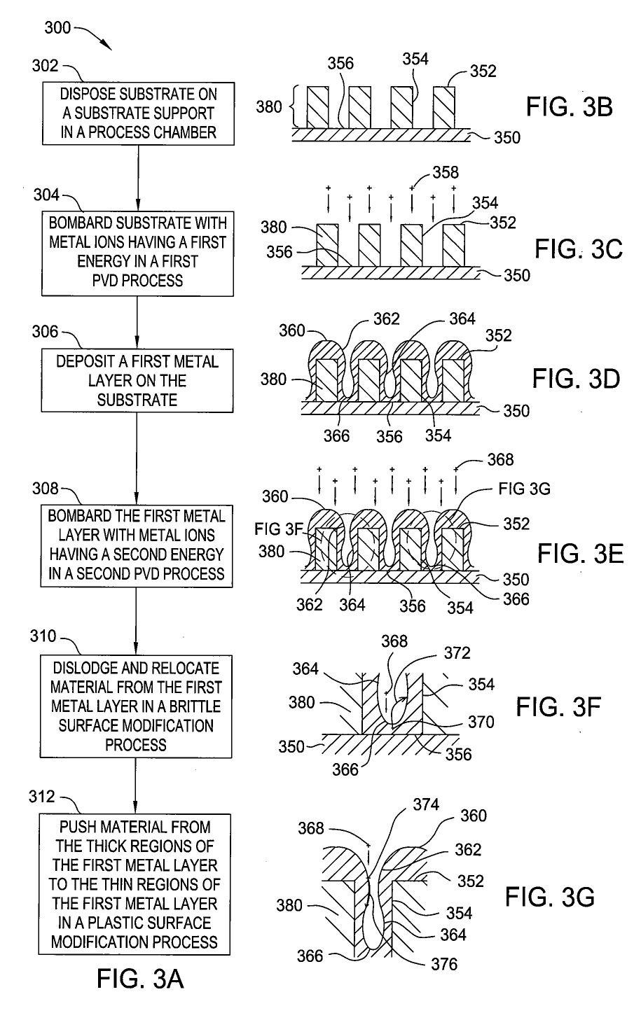

FIG. 3A is a flow diagram summarizing a method 300 according to another embodiment of the invention. At 302, a substrate to be processed is disposed on a substrate support in a processing chamber. An exemplary substrate is illustrated in FIG. 3B. The substrate has an underlying layer 350 and a patterned layer 380. The patterned layer has a field region 352 with openings that have side walls 354 and bottom portions 356. In some embodiments, the bottom portions 356 may expose portions of the underlying layer 350. In many embodiments, the underlying layer 350 may be conductive or semiconductive, while the patterned layer 380 is insulating or dielectric. Thus, the openings may expose the conductive or semiconductive material of the underlying layer 350.

At 304, the substrate is bombarded with metal ions having a first energy in a first PVD process. FIG. 3C illustrates the substrate of FIG. 3B undergoing the process of 304. The metal ions 358 are directed toward the substrate by use of physical or electrostatic alignment means, as described above, and impact the substrate surface. Due to the high directionality of the metal ion trajectories, most impacts happen on the field region 352, the upper part of the side walls 354, and the bottom portions 356 of the openings. At 306 a first metal layer is deposited on the substrate. FIG. 3D illustrates the first metal layer 360 deposited on the substrate covering the field region 352, side walls 354, and bottom portions 356 of the openings. An overhang portion 362 of the first metal layer 360 forms due to preferential deposition on the field region 352 and upper parts of the side walls 354. The overhang portions 362 narrow the openings, reducing ion flux into the openings. Due to the directionality of the ions, this reduced flux impacts deposition on the side walls 354 more than deposition on the bottom portions 356 of the openings, resulting in thick areas and thin areas of the deposited metal layer.

Similar to the embodiment described above in connection with FIGS. 2A-2E, the first metal layer 360 will generally have a curved surface or profile following the contours of the underlying substrate. The curvature of the surface will have similar characteristics to those of the embodiment of FIGS. 2A-2E, including embodiments having a substantially angular feature near the tops of the openings.

At 308, the first metal layer is bombarded with metal ions having a second energy in a second PVD process. The second energy will preferably be selected to reduce a surface energy of the first metal layer to support plastic flow of metal atoms on the surface of the metal layer. In some embodiments, the second energy will reduce the binding energy of atoms at the surface of the metal layer. In other embodiments, the second energy will reduce the lattice energy of the surface. In most embodiments, the second energy will adapt a temperature of the first metal layer, and layers deposited during the second deposition process, to support plastic flow of metal atoms on the surface of the metal layer. In some embodiments, the temperature of the metal layer during the second deposition process will be above about 50° C., such as between about 50° C. and about 200° C. or between about 80° C. and about 180° C., for example about 150° C. Thermal control may be employed to prevent the substrate from attaining a temperature at which metal begins to agglomerate. For example, a thermally controlled substrate support may be used to impart thermal flux to the substrate. FIG. 3E illustrates the substrate undergoing the second deposition process of 308. Ions 368 bombard the metal layer 360 deposited on the substrate, depositing on the surface and imparting energy to achieve the desired temperature.

At 310, the ions impact the deposited metal layer, dislodging and relocating material from the deposited metal layer in a brittle surface modification process. A brittle surface modification process is characterized by physical separation of particles from the surface upon impact. FIG. 3F is a detail view of a portion of the substrate undergoing the process of 310. Exemplary ion 368 has penetrated through the narrowed opening between overhang portions 362 of the deposited metal layer 360, and impacts the bottom portion 366 of the deposited metal layer 360. The energy of the impact is such that a particle of material 370 is ejected from the surface. The ejected particle 370 travels a trajectory 372 away from the bottom portion 366 of the deposited metal layer 360, and re-deposits on the side wall portion 364 of the deposited metal layer 360. Particles having an energy generally greater than about 100 eV may dislodge particles from the metal layer 360. In some embodiments, the incident particles have energy between about 100 eV and about 1,000 eV, such as between about 300 eV and about 700 eV, for example about 500 eV. The trajectory of the dislodged particle generally tends toward the side wall portion 364 of the metal layer 360 due to statistical exit angle of dislodged particles, increasing gas density higher in the opening, and electrostatic effects if the dislodged particle acquires a charge.

At 312, ions impact the deposited metal layer, pushing material from thick regions to thin regions along the surface in a plastic surface modification process. A plastic surface modification process is characterized by particles being dislodged from their location at the surface and moved to another location on the surface without being physically separated from the surface. The bonds holding the particles at the surface are stretched, and some are broken, but the particles are never completely unbonded from the surface. FIG. 3G is a detail view of a portion of the substrate undergoing the process of 312. Exemplary ion 368 impacts a thick region of the metal layer 360, perhaps impinging the overhang portion 362. At high angles of incidence and low energies, ion 368 will merely deposit on the surface of metal layer 360, but if incidence angle is low and energy is high enough, the momentum of ion 368 will transfer to one or more particles such as particle 374 at the surface and dislodge them from their position. In a plastic surface modification process, the particle 374 is not ejected from the surface of the metal layer 360, but moves along the surface remaining in contact therewith, as illustrated by trajectory 376. Many such particles will be pushed from the thick region to the thin region near the side wall portion 364 of metal layer 360. Some particles will undergo movement only parallel to the surface, pushing through atoms at the surface, while some particles may undergo movement perpendicular to the surface as well. Particles undergoing perpendicular movement may vacate their position in the metal matrix and move to a position on top of surface atoms, possibly forming a new surface layer or nucleation site, and possibly sinking back into the surface layer at another location. Other particles may move beneath the surface, resulting in uplift of layers nearer the surface. The interaction of deposition in 308, brittle surface modification at 310, and plastic surface modification at 312 produces an equalizing of thickness of the metal layer 360, resulting in a substantially conformal metal layer formed over the substrate. In embodiments featuring one or more substantially angular features near the top of the openings where side wall regions meet field regions, thickness of the deposited metal layer will grow near the top corner of the opening as metal ions are deposited during the second deposition process.

It should be noted that the methods 200 and 300 of FIGS. 2A and 3A are described in the context of ions bombarding the substrate surface, but neutral particles may also be advantageously used. Also, it should be noted that the processes of depositing, dislodging by a brittle surface modification process, and moving by a plastic surface modification process may proceed concurrently, simultaneously, or independently. In some embodiments, the second deposition process will begin before either the brittle or plastic surface modification processes, and the brittle surface modification process will begin before the plastic surface modification process begins. In other embodiments, the two surface modification processes may begin at about the same time. In some embodiments, the three processes will proceed concurrently or simultaneously, but may begin at different times. The brittle surface modification process may begin before the second deposition process ends, and the plastic surface modification process may begin before the brittle surface modification process ends.

FIG. 4 illustrates one embodiment of a PVD chamber 436. Examples of suitable PVD chambers are ALPS® plus and SIP ENCORE™ PVD processing chambers, both commercially available from Applied Materials, Inc., of Santa Clara, Calif.

Generally, the PVD chamber 436 contains a sputtering source, such as a target 442, and a substrate support 452 for receiving a semiconductor substrate 454 thereon and located within a grounded enclosure wall 450, which may be a chamber wall as shown or a grounded shield. The substrate support 452 is shown as a pedestal in the embodiment of FIG. 4, but in other embodiments, other types of substrate supports, such as edge rings or pins, may be used.

The chamber 436 includes a target 442 supported on and sealed, as by O-rings (not shown), to a grounded conductive aluminum adapter 444 through a dielectric isolator 446. The target 442 comprises the material to be deposited on the substrate 454 surface during sputtering, and may include copper, aluminum, cobalt, titanium, tantalum, tungsten, molybdenum, platinum, nickel, iron, niobium, palladium, and combinations thereof, which are used in forming metal silicide layers or conductive features. The target 442 may also include a bonded composite of a metallic surface layer and a backing plate of a more workable metal.

The substrate support 452 supports the substrate 454 to be sputter coated in planar opposition to the principal face of the target 442. Substrate supports such as substrate support 452 have a planar substrate-receiving surface disposed generally parallel to the sputtering surface of the target 442. The substrate support 452 is vertically movable through a bellows 458 connected to a bottom chamber wall 460 to allow the substrate 454 to be transferred onto the substrate support 452 through a load lock valve (not shown) in the lower portion of the chamber 436 and thereafter raised to a deposition position. Processing gas is supplied from a gas source 462 through a mass flow controller 464 into the lower part of the chamber 436. Gases exit the chamber through conduit 468 with valve 466.

A controllable DC power source 478 coupled to the chamber 436 may be used to apply a negative voltage or bias to the target 442. An RF power supply 456 may be connected to the substrate support 452 in order to induce a negative DC self-bias on the substrate 454, but in other applications the substrate support 452 may be grounded or left electrically floating.

A rotatable magnetron 470 is positioned in back of the target 442 and includes a plurality of horseshoe magnets 472 supported by a base plate 474 connected to a rotation shaft 476 coincident with the central axis of the chamber 436 and the substrate 454. The horseshoe magnets 472 are arranged in closed pattern typically having a kidney shape. The magnets 472 produce a magnetic field within the chamber 436, generally parallel and close to the front face of the target 442 to trap electrons and thereby increase the local plasma density, which in turn increases the sputtering rate. The magnets 472 produce an electromagnetic field around the top of the chamber 436, and magnets 472 are rotated to rotate the electromagnetic field which influences the plasma density of the process to more uniformly sputter the target 442.

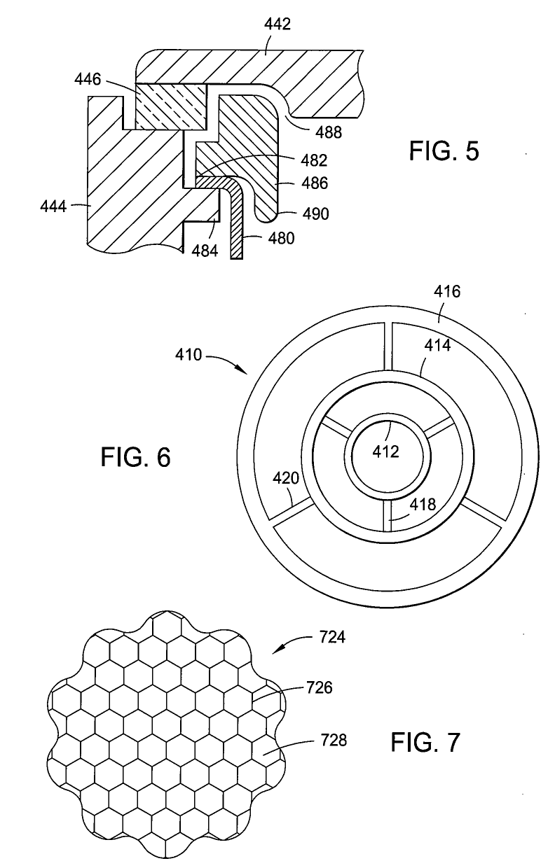

The chamber 436 of the invention includes a grounded bottom shield 480 having, as is more clearly illustrated in the exploded cross-sectional view of FIG. 5, an upper flange 482 supported on and electrically connected to a ledge 484 of the adapter 444. A dark space shield 486 is supported on the flange 482 of the bottom shield 480, and fasteners (not shown), such as screws recessed in the upper surface of the dark space shield 486 fix it and the flange 482 to the adapter ledge 484 having tapped holes receiving the screws. This metallic threaded connection allows the two shields 480, 486 to be grounded to the adapter 444. The adapter 444 in turn is sealed and grounded to an aluminum chamber sidewall 450. Both shields 480, 486 are typically formed from hard, non-magnetic stainless steel.

The dark space shield 486 has an upper portion that closely fits an annular side recess of the target 442 with a narrow gap 488 between the dark space shield 486 and the target 442 which is sufficiently narrow to prevent the plasma from penetrating, hence protecting the dielectric isolator 446 from being sputter coated with a metal layer, which would electrically short the target 442. The dark space shield 486 also includes a downwardly projecting tip 490, which prevents the interface between the bottom shield 480 and dark space shield 486 from becoming bonded by sputter deposited metal.

Returning to the overall view of FIG. 4, the bottom shield 480 extends downwardly in an upper generally tubular portion 494 of a first diameter and a lower generally tubular portion 496 of a smaller second diameter to extend generally along the walls of the adapter 444 and the chamber wall 450 to below the top surface of the substrate support 452. It also has a bowl-shaped bottom including a radially extending bottom portion 498 and an upwardly extending inner portion 400 just outside of the substrate support 452. A cover ring 402 rests on the top of the upwardly extending inner portion 400 of the bottom shield 480 when the substrate support 452 is in its lower, loading position, but rests on the outer periphery of the substrate support 452 when it is in its upper, deposition position to protect the substrate support 452 from sputter deposition. An additional deposition ring (not shown) may be used to shield the periphery of the substrate 454 from deposition.

The chamber 436 may also be adapted to provide a more directional sputtering of material onto a substrate. In one aspect, directional sputtering may be achieved by positioning a collimator 410 between the target 442 and the substrate support 452 to provide a more uniform and symmetrical flux of deposition material on the substrate 454.

A metallic ring collimator 410, such as the Grounded Ring collimator, is illustrated in the embodiment of FIG. 4. The ring collimator 410 rests on the ledge portion 406 of the bottom shield 480, thereby grounding the collimator 410. The ring collimator 410 includes an outer tubular section and at least one inner concentric tubular section, for example, three concentric tubular sections 412, 414, 416 linked by cross struts 418, 420 as shown in FIG. 6. The outer tubular section 416 rests on the ledge portion 406 of the bottom shield 480. The use of the bottom shield 480 to support the collimator 410 simplifies the design and maintenance of the chamber 436. At least the two inner tubular sections 412, 414 are of sufficient height to define high aspect-ratio apertures that partially collimate the sputtered particles. Further, the upper surface of the collimator 410 acts as a ground plane in opposition to the biased target 442, particularly keeping plasma electrons away from the substrate 454.

Another type of collimator usable with the invention is a honeycomb collimator 724, partially illustrated in the plan view of FIG. 7 having a mesh structure with hexagonal walls 726 separating hexagonal apertures 728 in a close-packed arrangement. An advantage of the honeycomb collimator 724 is, if desired, the thickness of the collimator 724 can be varied from the center to the periphery of the collimator 724, usually in a convex shape, so that the apertures 728 have aspect ratios that are likewise varying across the collimator 724. The collimator may have one or more convex sides. This allows the sputter flux density to be tailored across the substrate, permitting increased uniformity of deposition. Average sputter flux density of the collimator may also be affected by the average aspect ratio. In most embodiments, a honeycomb collimator such as collimator 724 will have aspect ratio between about 2:1 and about 5:1, such as about 3:1.

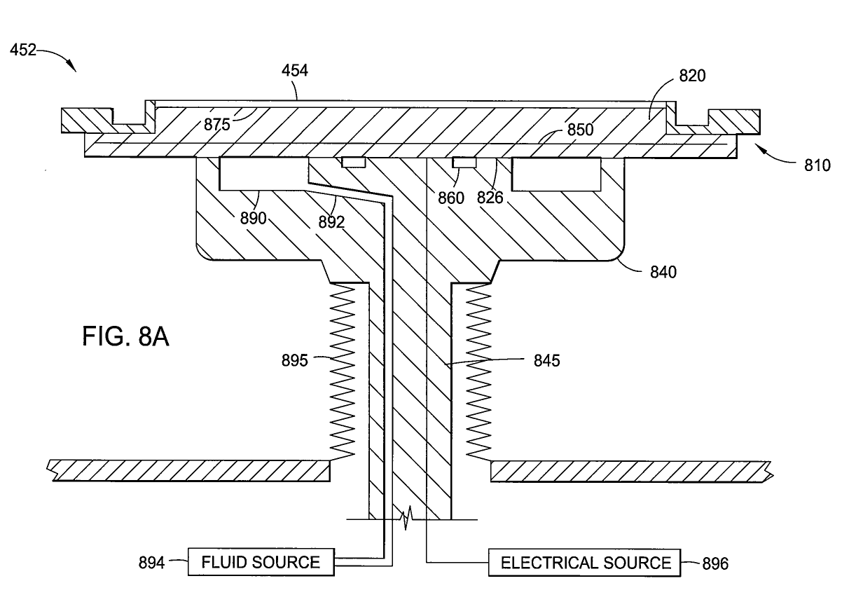

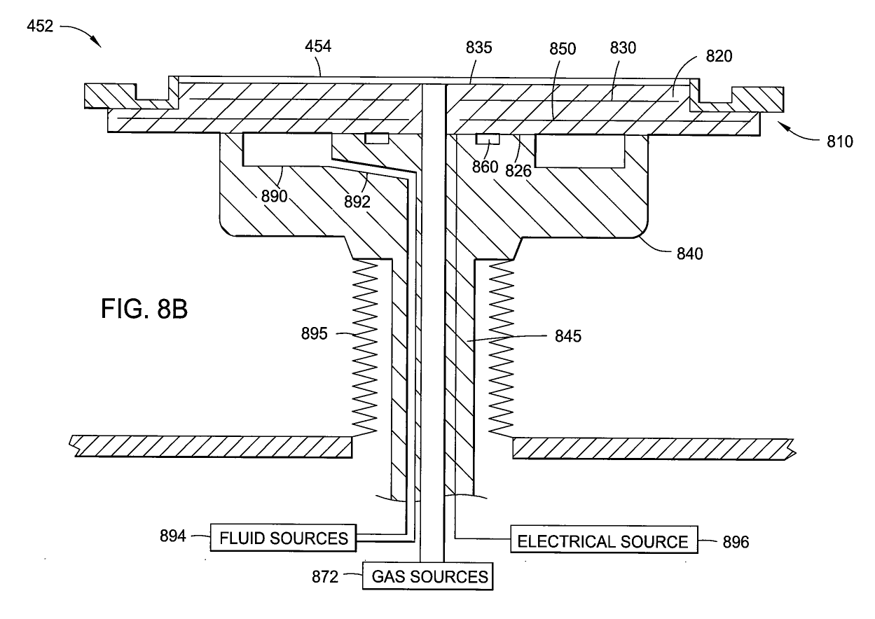

One embodiment of a substrate support 452 is shown in FIG. 8A. The substrate support 452 is suitable for use in a PVD process. Generally, the substrate support 452 includes a thermal control portion 810 disposed on a base 840 coupled to a shaft 845.

The thermal control portion 810 generally includes one or more heating elements 850 disposed in a thermally conducting material 820 and a substrate receiving surface 875. The thermally conducting material 820 may be any material that has sufficient thermal conductance at operating temperatures for efficient heat transfer between the heating elements 850 and a substrate support surface 875. An example of the conducting material is steel. The substrate support surface 875 may include a dielectric material and typically includes a substantially planar receiving surface for a substrate 454 disposed thereon.

The heating elements 850 may be resistive heating elements, such as electrically conducting wires having leads embedded within the conducting material 820, and are provided to complete an electrical circuit by which electricity is passed through the conducting material 820. An example of a heating element 850 includes a discrete heating coil disposed in the thermally conducting material 820. Electrical wires connect an electrical source 896, such as a voltage source, to the ends of the electrically resistive heating coil to provide energy sufficient to heat the coil. The coil may take any shape that covers the area of the substrate support 452. More than one coil may be used to provide additional heating capability, if needed.

Fluid channels 890 may be coupled to a surface 826 of the thermal control portion 810 and may provide for either heating or cooling of the substrate support 452. The fluid channels 890 may include a concentric ring or series of rings (not shown), or other desired configuration, having fluid inlets and outlets for circulating a liquid from a remotely located fluid source 894. The fluid channels 890 are connected to the fluid source 894 by fluid passage 892 formed in the shaft 845 of substrate support 452. Embodiments of the substrate support 452, including both heating elements 850 coupled to an electrical source 896 and fluid channels 890 cooled by a thermal medium passing through fluid passage 892 connected to the fluid source 894, i.e., a liquid heat exchanger, generally achieve thermal control of the surface 875 of the substrate support 452.

Temperature sensors 860, such as a thermocouple, may be attached to or embedded in the substrate support 452, such as adjacent the thermal control portion 810, to monitor temperature in a conventional manner. For example, measured temperature may be used in a feedback loop to control electric current applied to the heating elements 850 from the electrical source 896, such that substrate temperature can be maintained or controlled at a desired temperature or within a desired temperature range. A control unit (not shown) may be used to receive a signal from temperature sensors 860 and control the heat electrical source 896 or a fluid source 894 in response.

The electrical source 896 and the fluid source 894 of the heating and cooling components are generally located external of the chamber 436. The utility passages, including the fluid passage 892, are disposed axially along the base 840 and shaft 845 of the substrate support 452. A protective, flexible sheath 895 is disposed around the shaft 845 and extends from the substrate support 452 to the chamber wall (not shown) to prevent contamination between the substrate support 452 and the inside of the chamber 436.

The substrate support 452 may further contain gas channels (not shown) fluidly connecting with the substrate receiving surface 875 of the thermal control portion 810 to a source of backside gas (not shown). The gas channels define a backside gas passage of a heat transfer gas or masking gas between the thermal control portion 810 and the substrate 454.

FIG. 8B illustrates another embodiment of the substrate support 452 having an electrostatic chuck mounted to or forming the thermal control portion 810 of the substrate support 452. The thermal control portion 810 includes an electrode 830 and a substrate receiving surface 875 coated with a dielectric material 835. Electrically conducting wires (not shown) couple the electrodes 830 to a voltage source (not shown). A substrate 454 may be placed in contact with the dielectric material 835, and a direct current voltage is placed on the electrode 830 to create an electrostatic attractive force to grip the substrate.

Generally, the electrodes 830 are disposed in the thermally conducting material 820 in a spaced relationship with the heating elements 850 disposed therein. The heating elements 850 are generally disposed in a vertically spaced and parallel manner from the electrodes 830 in the thermally conducting material 820. Typically, the electrodes 830 are disposed between the heating elements 850 and the substrate receiving surface 875 though other configurations may be used.

Gases may be provided to the substrate receiving surface 875 of the substrate support 452 from gas sources 872. Such gases may assist in thermal control of the substrate by contacting the back side of the substrate. Gases may travel through a central conduit of the shaft 875 and exit through openings in the substrate receiving surface 875 and the dielectric coating 835, if present.

The embodiments of the substrate support 452 described above may be used to support a substrate in a high vacuum anneal chamber. The high vacuum anneal chamber may include substrate support pedestals 452 disposed in a PVD chamber, such as the chamber 436 described herein, with a blank target disposed therein or without a target and without bias coupled to either the target or substrate support pedestal.

Embodiments of the substrate support 452 are described above and are provided for illustrative purposes and should not be construed or interpreted as limiting the scope of the invention. For example, suitable electrostatic chucks that may be used for the support pedestal include MCA™ Electrostatic E-chuck or Pyrolytic Boron Nitride Electrostatic E-Chuck, both available from Applied Materials, Inc., of Santa Clara, Calif.

While the foregoing is directed to embodiments of the invention, other and further embodiments of the invention may be devised without departing from the basic scope thereof.

What is claimed is:

1. A method of processing a substrate having openings formed in a field region, comprising:
depositing a metal layer on the substrate to form a deposited metal layer;
subjecting the deposited metal layer to a brittle surface modification process; and
subjecting the deposited metal layer to a plastic surface modification process.

2. The method of claim 1, wherein the deposited metal layer has one or more substantially angular features at the bottom of a capping portion of the deposited metal layer, the capping portion covering a field region of the substrate.

3. The method of claim 1, wherein the openings in the field region of the substrate have a width, and the deposited metal layer comprises a curved surface with a radius of curvature less than about half the width of the openings.

4. The method of claim 3, wherein the curved surface is a substantially angular feature at the bottom of a capping portion of the deposited metal layer, the capping portion covering a field region of the substrate.

5. The method of claim 3, wherein the deposited metal layer forms overhang portions at the tops of the openings, and side wall portions along the side walls of the openings.

6. The method of claim 5, wherein the brittle surface modification process comprises bombarding the deposited metal layer with metal ions, such that previously deposited material is ejected and redeposited at other locations.

7. The method of claim 5, wherein the plastic surface modification process comprises pushing material from the deposited metal layer along the surface of the deposited metal layer from the overhang portions to other locations.

8. A method of depositing a conformal metal layer in openings formed in a field region of a substrate, comprising:
disposing the substrate on a substrate support in a processing chamber;
depositing a first metal layer having thick regions and thin regions on the substrate in a physical vapor deposition process;
simultaneously depositing a second metal layer over the first metal layer in a physical vapor deposition process, ejecting material from the first metal layer and redepositing the ejected material with the second metal layer, and pushing metal from the thick regions of the first metal layer to the thin regions of the first metal layer.

9. The method of claim 8, wherein the substrate is exposed to an electrical bias at a first energy level during deposition of the first metal layer and a second energy level during deposition of the second metal layer, and the second energy level is at least three times higher than the first energy level.

10. The method of claim 8, wherein the substrate is exposed to an electrical bias at a first energy level between about 50 Watts and 150 Watts during deposition of the first metal layer and a second energy level between about 800 Watts and about 1,200 Watts during deposition of the second metal layer.

11. The method of claim 8, wherein depositing the first metal layer and depositing the second metal layer each comprises directing charged particles toward the substrate at an angle of incidence of at least 60° with respect to the field region of the substrate.

12. The method of claim 11, wherein charged particles having an angle of incidence less than 60° with respect to the field region of the substrate are filtered using a collimator.

13. The method of claim 8, wherein depositing the second metal layer on the substrate comprises reducing a surface energy of the first metal layer by at least about 50%.

14. The method of claim 8, wherein pushing metal from the thick regions of the first metal layer to the thin regions of the first metal layer comprises reducing a surface energy of the first metal layer by at least about 50% and applying a shear force to the first metal layer.

15. The method of claim 14, wherein the substrate is exposed to an electrical bias at a first energy level during deposition of the first metal layer and a second energy level during deposition of the second metal layer, and the second energy level is at least three times higher than the first energy level.

16. The method of claim 15, wherein depositing the first metal layer and depositing the second metal layer each comprises directing charged particles toward the substrate at an angle of incidence of at least 60° with respect to the field region of the substrate.

17. A method of depositing a conformal metal layer on a substrate having a field region and openings with sidewalls and bottom portions in the field region, comprising:
disposing the substrate on a substrate support in a process chamber;
depositing a first metal layer on the substrate by exposing the substrate to a first physical vapor deposition process comprising directing metal ions toward a surface of the substrate using a first electrical bias less than about 100V, wherein the first metal layer has thick regions at the top of the sidewalls and bottom portions of the openings and thin regions on the sidewalls of the openings; and
exposing the substrate to a second physical vapor deposition process comprising directing metal ions toward a surface of the substrate using a second electrical bias of at least 250V, wherein the second physical vapor deposition process comprises:
depositing a second metal layer on the substrate;
dislodging material from the first metal layer at the bottom portions of the openings by bombarding the first metal layer with metal ions, and relocating the dislodged material; and
moving material from the thick regions at the top of the sidewalls to the thin regions on the sidewalls.

18. The method of claim 17, further comprising reducing surface energy of the first metal layer by at least about 50%.

19. The method of claim 17, further comprising reducing surface energy of the first metal layer by at least about 50%, wherein the first electrical bias is applied at a power level no more than 150 Watts and the second electrical bias is applied at a power level no less than about 600 Watts.

20. The method of claim 19, wherein a substrate temperature is controlled at less than about 200° C. during the second physical vapor deposition process.

21. The method of claim 17, wherein the dislodging begins before the depositing ends and the moving begins before the dislodging ends.
